(19) United States
(12) Patent Application Publication
(10) Pub. No.: US 2025/0238573 A1
(43) Pub. Date: Jul. 24, 2025

(54) SYSTEMS, METHODS, AND DEVICES FOR ON-DEMAND ENVIRONMENT SIMULATION

(71) Applicant: Salesforce, Inc., San Francisco, CA (US)

(72) Inventor: Charlie ISAACS, Annapolis, MD (US)

(73) Assignee: Salesforce, Inc., San Francisco, CA (US)

(21) Appl. No.: 18/421,680

(22) Filed: Jan. 24, 2024

(51) Int. Cl. G06F 30/20

(52) U.S. Cl. CPC G06F 30/20

(57) ABSTRACT

Systems, methods, and devices provide on-demand environment simulation. A computing platform may be implemented using a server system, where the computing platform is configurable to cause receiving a message from a graphics engine, the message identifying at least one object included in a graphics rendering environment, and further identifying status information associated with the at least one object, and identifying, based on the received message, an instance of an on-demand application associated with the graphics rendering environment. The computing platform may be further configurable to cause mapping the status information to an operation associated with the instance of the on-demand application based on a designated mapping of graphics engine assets to the instance of the on-demand application.

### FIELD OF TECHNOLOGY

This patent application relates generally to on-demand applications, and more specifically to simulation tools for such on-demand applications.

### BACKGROUND

“Cloud computing” services provide shared resources, applications, and information to computers and other devices upon request. In cloud computing environments, services can be provided by one or more servers accessible over the Internet rather than installing software locally on in-house computer systems. Users can interact with cloud computing services to undertake a wide range of tasks. Such cloud computing environments may be used to host distributed applications that may be used to support various distributed services provided to users. Conventional techniques for providing such services remain limited because they are not able to efficiently and effectively simulate different scenarios associated with such distributed applications.

### BRIEF DESCRIPTION OF THE DRAWINGS

The included drawings are for illustrative purposes and serve only to provide examples of possible structures and operations for the disclosed inventive systems, apparatus, methods, and computer program products for on-demand environment simulation. These drawings in no way limit any changes in form and detail that may be made by one skilled in the art without departing from the spirit and scope of the disclosed implementations.

FIG. 1 illustrates an example of a system for on-demand environment simulation, configured in accordance with some embodiments.

FIG. 2 illustrates another example of a system for on-demand environment simulation, configured in accordance with some embodiments.

FIG. 3 illustrates an example of a method for on-demand environment simulation, performed in accordance with some embodiments.

FIG. 4 illustrates another example of a method for on-demand environment simulation, performed in accordance with some embodiments.

FIG. 5 illustrates an additional example of a method for on-demand environment simulation, performed in accordance with some embodiments.

FIG. 6 illustrates another example of a method for on-demand environment simulation, performed in accordance with some embodiments.

FIG. 7 illustrates an example of a method for on-demand environment simulation, performed in accordance with some embodiments.

FIG. 8 illustrates an additional example of a method for on-demand environment simulation, performed in accordance with some embodiments.

FIG. 9 shows a block diagram of an example of an environment 910 that includes an on-demand database service configured in accordance with some implementations.

FIG. 10A shows a system diagram of an example of architectural components of an on-demand database service environment 1000, configured in accordance with some implementations.

FIG. 10B shows a system diagram further illustrating an example of architectural components of an on-demand database service environment, in accordance with some implementations.

FIG. 11 illustrates one example of a computing device.

### DETAILED DESCRIPTION

Cloud computing platforms may be used to host distributed applications that may be provided on-demand, and as software as a service (Saas) applications. Accordingly, such computing platforms may be used to host various instances of distributed applications configured to provide various features to a user. In one example, such an on-demand application may be an application such as that provided by Force.com®, which may be configured to provide work flow management features for a user. For example, a user may be provided with a workspace and user interface in which the user may create a sequential representation of various operations that may represent a process flow. The sequential representation may be stored as a process flow data structure, and may include various data objects representative of operations, as well as connectors between such data objects identifying dependencies. Some techniques for implementing such process flow data structures do not provide the ability to simulate different scenarios for such process flow data structures, or the ability to do so within a simulated three-dimensional space.

Embodiments disclosed herein provide the ability leverage a three-dimensional graphical environment to interact with and simulate scenarios and functionality of process flows implemented within an application hosted by a computing platform. As will be discussed in greater detail below, the graphical environment may be implemented within a graphics rendering environment that uses a graphics engine. The graphical environment may be configured to have various different assets with associated physical properties. Such assets may be mapped bidirectionally to components of the process flow data structure. In this way, changes to assets within the graphical environment may trigger operations within the process flow, and visa versa. Accordingly, simulated scenarios may be created within the graphical environment, and used to generate simulated results of process flows within the computing platform.

In one example, a process flow may be implemented in a computing platform for an organization, such as an airline. Accordingly, the organization may have an account with an on-demand application hosted by the computing platform, and may have associated storage within a multi-tenant database oof the computing platform. In this example, the airline may have created various different process flows to determine operations performed in response to events on an airplane. For example, the process flow may be a data structure that includes an initial data object identifying an event, such as a door opening. The process flow data structure may additionally include subsequent data objects identifying subsequent operations to be performed in response to the event occurring. For example, such subsequent data objects may be generation of a notification message, disarming or triggering of one or more alarms, as well as various other operations such as commands issued to crew members.

In various embodiments, a graphics rendering environment may be implemented for the process flow data structure, and it may be configured to simulate the airplane and its associated components. Accordingly, a graphics engine, such as Unity® or Unreal®, may be used to construct a three-dimensional representation of an airplane that has various relevant components of the airplane, such as a fuselage, doors, on-board sensors, as well as any other suitable components relevant to the associated process flow data structure. As will be discussed in greater detail below, the three-dimensional representation may be generated by an entity, such as a user, and may be created using assets of the graphics rendering environment and associated physical properties. Accordingly, the three-dimensional representation may be constructed out of assets that are data objects native to the graphics rendering environment and graphics engine.

As will discussed in greater detail below, assets in the three-dimensional representation may be mapped to operations included in the process flow data structure of the computing platform. Accordingly, opening a door of the airplane in the three-dimensional representation may be detected as an event that is mapped to an operation of the process flow data structure, and may trigger the corresponding portion of the flow within the process flow data structure. As will also be discussed in greater detail below, such mapping and connectivity may be provided by a service layer of the computing platform.

Moreover, a user interface may be provided to a user that is configured to enable the user to interact with the three-dimensional representation via a custom interface. Accordingly, the user may be provided with a visual representation of the airplane, as well as various buttons or controls, such as a button labeled “open door”. Such buttons and controls may be configured and implemented based on operational steps included the process flow data structure and/or may be determined by an entity, such as a user. In this way, the user may be provided with a custom interface on a client device that enables the user to simulate different scenarios via a simplified custom interface.

In another example, a process flow data structure may be configured to simulate a sequence of events that may occur in response to a power transformer failure. In this example, the process flow data structure may be implemented by an organization, such as a manufacturer, within the computing platform. As discussed above, a three-dimensional representation may be generated within the graphics rendering environment that includes assets representing one or more power transformers. For example, the three-dimensional representation may be a rooftop on which four power transformers are implemented. Each transformer may be mapped to operations included in the process flow data structure that may identify operations that occur when a power transformer fails, such as shutting off of power and notification of a repair crew. In this example, the user may simulate failure of one or more transformers to see the results of such scenarios and, for example, whether or not enough repair crews are available. Moreover, the user may experiment with different configurations and distances between the power transformers to see if results vary. In this example, physics parameters of the physics engine may be leveraged to simulate physical parameters, such as temperature, of the power transformers thus allowing physics simulation capabilities of the graphics engine to determine if process flow triggering events have occurred.

In an additional example, a process flow data structure may be configured to simulate a sequence of events that may occur in response to a mechanical failure that may, for example, occur in an elevator. In this example, the process flow data structure may be implemented by an organization, such as an elevator repair service, within the computing platform. As discussed above, a three-dimensional representation may be generated within the graphics rendering environment that includes assets representing one or more elevators within a building. For example, the three-dimensional representation may be a multi-story building that has three elevators. Each elevator may be mapped to operations included in the process flow data structure that may identify operations that occur when a mechanical problem arises with an elevator, such as disabling the elevator and notifying a repair crew. In this example, the user may simulate failure of one or more elevators to see the results of such scenarios and, for example, whether or not enough repair crews are available. Moreover, pathing provided by the graphics rendering environment may be used to simulate and estimate repair times as a repair crew traverses the three-dimensional representation of the building. In this way, the elevator repair service may simulate specific failure conditions within a specific configuration of a building to see if existing process flow data structures are sufficient or need to be modified.

In another example, a three-dimensional representation of a car may be generated and mapped to various process flow data structures. In this example, the three-dimensional representation of the car may include structural components of the car, such as a body, doors, engine, wheels, brakes, etc., and may also include various sensors associated with such structural components configured to generate a signal based on simulated conditions, such as low tire pressure, a door being open, as well as various other condition. Such sensors may be mapped to different process flow data structures, and a user may also configure the three-dimensional representation of the car to simulate wear conditions in which components become worn and need replacing, as may be the case when brakes need to be replaced. Accordingly, a user may provide an input that specifies wear parameters and observe the resulting triggering of process flow data structures within the computing platform. In one example, the user may specify the brakes are worn and need to be replaced. This may trigger a first process flow data structure recommending maintenance to the user. This may also trigger a second process flow data structure that is a customer service process flow, such as a customer survey or additional lease offer. In this way, multiple sensors within the three-dimensional representation of the car may independently trigger different process flows, or may interact with each other in accordance with the graphics engine to trigger multiple process flows.

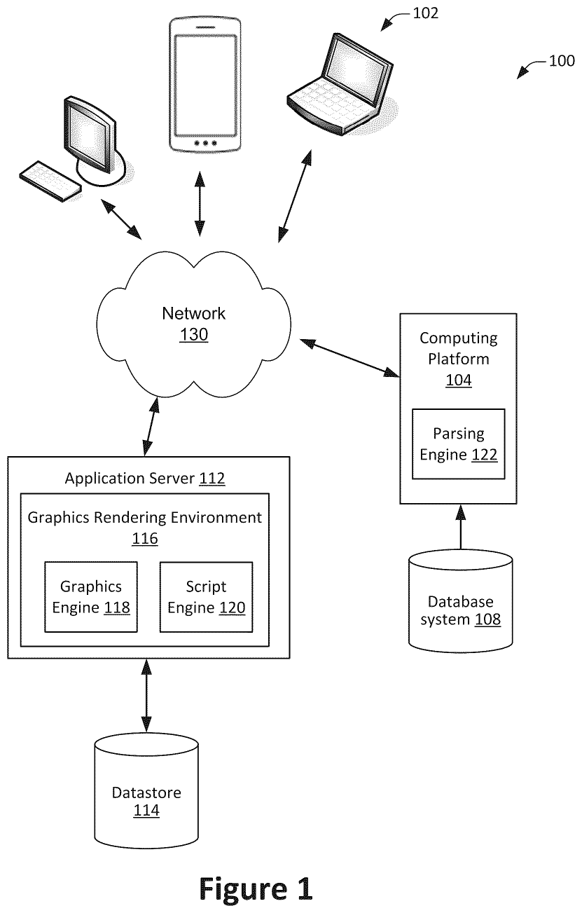

FIG. 1 illustrates an example of a system for on-demand environment simulation, configured in accordance with some embodiments. As will be discussed in greater detail below, components of a computing platform may be configured to communicate with a graphics rendering environment to enable simulation and modeling of on-demand applications hosted by the computing platform using the graphics rendering environment. More specifically, the graphics rendering environment may be configured to provide a sandbox environment that may be used to simulate different operational scenarios for the on-demand application.

In various embodiments, system 100 includes various client machines, which may also be referred to herein as user devices, such as client machine 102. In various embodiments, client machine 102 is a computing device accessible by a user. For example, client machine 102 may be a desktop computer, a laptop computer, a mobile computing device such as a smartphone, or any other suitable computing device. Accordingly, client machine 102 includes one or more input and display devices, and is communicatively coupled to communications network 130, such as the internet. In various embodiments, client machine 102 is configured to execute one or more applications that may utilize a user interface. Accordingly, a user may provide one or more inputs via client machine 102. In various embodiments, a user interface may be used to present a webpage to the user. Accordingly, the user interface may utilize a web browser executed on client machine 102.

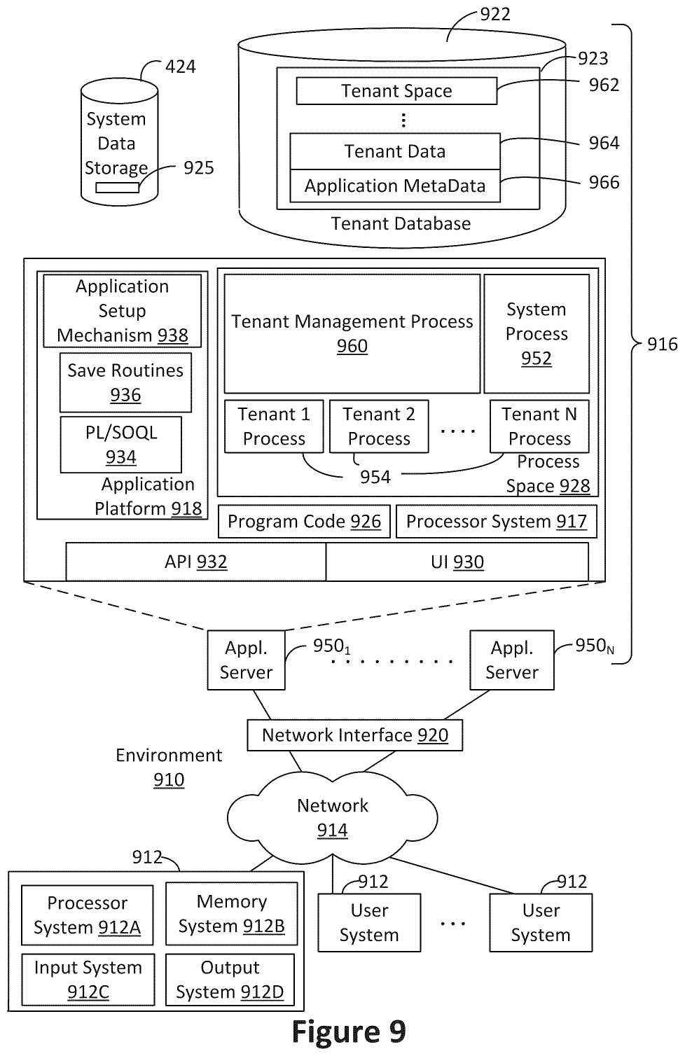

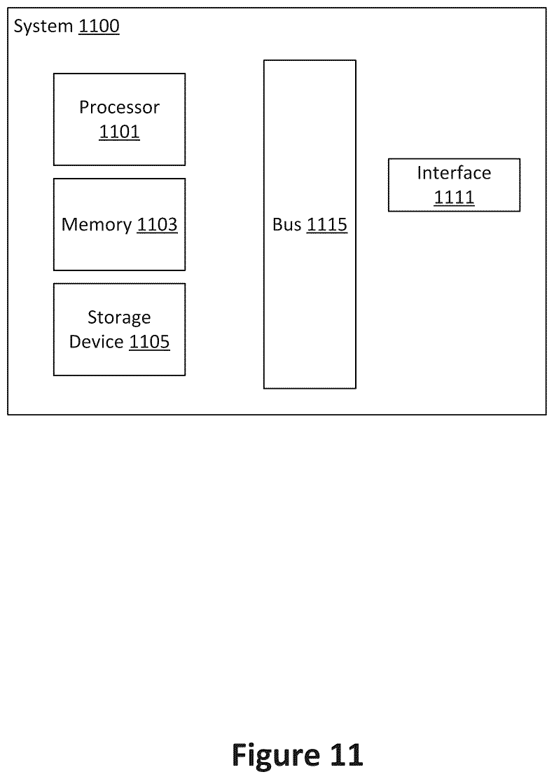

System 100 further includes application server 112. In some embodiments, application server 112 may be implemented as discussed in greater detail below with reference to FIG. 9 and FIG. 11. In some embodiments, application server 112 is configured to generate and serve webpages that may be viewed by a user via one or more devices, such as client machine 102. Accordingly, in some embodiments, application server 112 includes a web server.

In various embodiments, application server 112 further includes graphics rendering environment 116 which is configured to include graphics engine 118. As will be discussed in greater detail below, graphics rendering environment 116 may be an application that is configured to provide a three-dimensional design environment that supports graphical rendering of assets as well as simulated physics parameters for such assets. Accordingly, graphics rendering environment 116 may be an application configured to provide a user with a graphical user interface used to access and interact with such an environment. The application may further include various libraries of assets, such as templates or pre-defined three-dimensional objects, as well as a user interface that allows configuration of physical parameters of such three dimensional objects. The physics parameters and other rendering operations may be performed by graphics engine 118. In various embodiments, graphics engine 118 may be a graphics engine such as Unity or Unreal, and graphics rendering environment 116 may be an application configured to provide design capabilities and asset library access on top of graphics engine 118. In various embodiments, such asset libraries as well as other associated information may be stored in a datastore, such as datastore 114.

In various embodiments, graphics rendering environment 116 further includes script engine 120 which is configured to generate application program interface (API) calls based on assets and actions included within graphics rendering environment 116. For example, script engine 120 may be implemented using a scripting language, such as CS-Script. Script engine 120 may read information from graphics files and data records included in graphics rendering environment 116, and may map combinations of assets and actions to particular API calls based on a designated mapping representing in the scripting language. Such a designated mapping may have been generated by an entity, such as a manufacturer, developer, and/or user, and may also be configured by an entity, such as a user, to modify and update operation of script engine 120. In various embodiments, the API calls may be transmitted to a component of computing platform 104, discussed in greater detail below. Accordingly, the API calls may be transmitted to a service layer of computing platform 104, and the service layer may handle routing of the API call to components of a data layer if appropriate and as will be discussed in greater detail below.

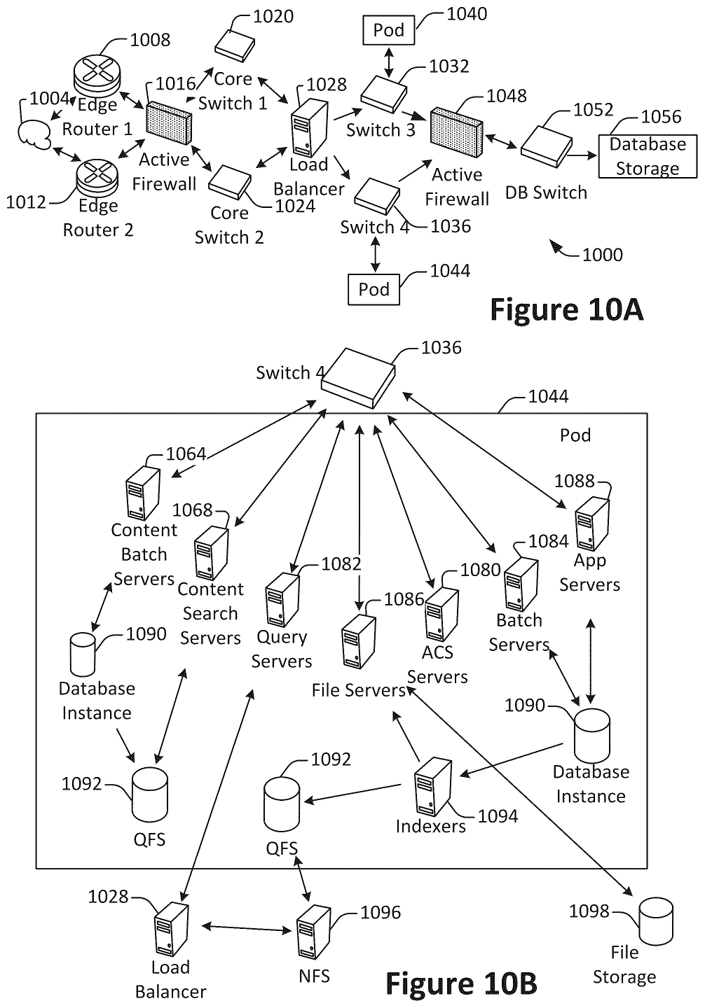

System 100 additionally includes computing platform 104. As shown in FIG. 1, computing platform may also be coupled to database system 108. As discussed in greater detail below with reference to FIG. 9, FIG. 10, and FIG. 11, computing platform 104 is configured to host one or more distributed on-demand applications. For example, computing platform 104 may be configured to host one or more on-demand applications provided by Salesforce.com®. Moreover, computing platform 104 may also include an interface configured to handle function calls, also referred to herein as server calls, generated by application server 112. The interface may be implemented using components of a database system, such as an API. Accordingly, application data may be stored and maintained by components of computing platform 104.

As will be discussed in greater detail below, on-demand applications may have underlying data models defining relationships and dependencies between data objects, and also defining parameters of general data objects. In some embodiments, an on-demand application may be configured to support one or more operations, such as workflow management. Accordingly, the on-demand application may provide a user interface through which a user may generate and manage workflows for an organization, and data objects within the workflow may be linked to data stored in multi-tenant customer relationship management (CRM) database, such as database system 108. It will be appreciated that the on-demand application may be configured to implement and manage multiple different process flows for an organization that may be a tenant of the multi-tenant database. Additional examples of such flows and sequences of operations will be discussed in greater detail below.

In various embodiments, computing platform 104 is also configured to implement communicative coupling between graphics rendering environment 116 and the on-demand application hosted by computing platform 104. Accordingly, assets included in and rendered in graphics rendering environment 116 may be mapped to process flows hosted by computing platform 104 such that interactions with and changes to one are reflected in the other. For example, changes to an asset included in graphics rendering environment 116 may be mapped to a change in a process flow of the on-demand application hosted by computing platform 104. In this way, graphics rendering environment 116 may be configured to provide a virtual simulation of assets that represent processes and operations within the on-demand application hosted by computing platform 104.

In various embodiments, computing platform 104 includes parsing engine 122 which may also be implemented using a scripting language, and may be configured to interpret and translate messages received from graphics rendering environment 116. More specifically, calls generated by script engine 120 may be included in a message that is transmitted from graphics rendering environment 116 and application server 112, and received at computing platform 104. In some embodiments, parsing engine 122 is included in a service layer of computing platform 104, and may, for example, be implemented as a service layer process within Mulesoft®. As will be discussed in greater detail below, parsing engine 122 may extract API calls from the received message, map them to their respective data model and process flow components, and also handle any additional mapping or translation of such API calls that may be appropriate.

As similarly discussed above, computing platform 104 is coupled to database system 108, which is configured to provide data storage utilized by computing platform 104. In various embodiments, database system 108 includes system data storage and a tenant database, as discussed in greater detail below with reference to FIG. 9. In various embodiments, computing platform 104 is also coupled to communications network 130, and is communicatively coupled to application server 112 and client machine 102.

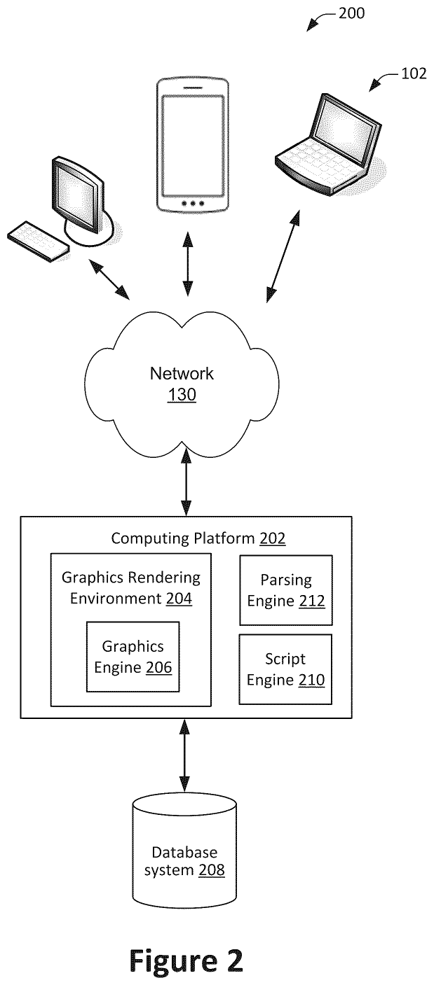

FIG. 2 illustrates another example of a system for on-demand environment simulation, configured in accordance with some embodiments. As similarly discussed above, components of a computing platform may be configured to communicate with a graphics rendering environment to enable simulation and modeling of on-demand applications hosted by the computing platform using the graphics rendering environment. Accordingly, a system, such as system 200, may include client machine 102 and communications network 130, as similarly discussed above.

In various embodiments, system 200 also includes computing platform 202 coupled to database system 208. As similarly discussed above, computing platform 202 may be configured to host an on-demand application that may have an associated data model, an instance configured for one or more tenants of a multi-tenant database, and one or more process flows specific to that tenant. In various embodiments, computing platform 202 may be configured to include graphics rendering environment 204 and graphics engine 206. Accordingly, as shown in FIG. 2, graphics rendering environment 204 may be integrated within computing platform 202, and may also store data, such as asset libraries, within a shared storage system, such as database system 208. In this way, interactions between computing platform 202 and graphics rendering environment 204 may occur within computing platform 202, and communication via a network, such as communications network 130 is not needed. Moreover, as shown in FIG. 2, script engine 210 and parsing engine 212 may be implemented within computing platform 202. As discussed above, script engine 210 and parsing engine 212 may be configured to handle mapping of assets and actions within graphics rendering environment 204 to process flows and data models of computing platform 202. In some embodiments, script engine 210 and parsing engine 212 may be integrated within a single component implemented within a service layer of computing platform 202.

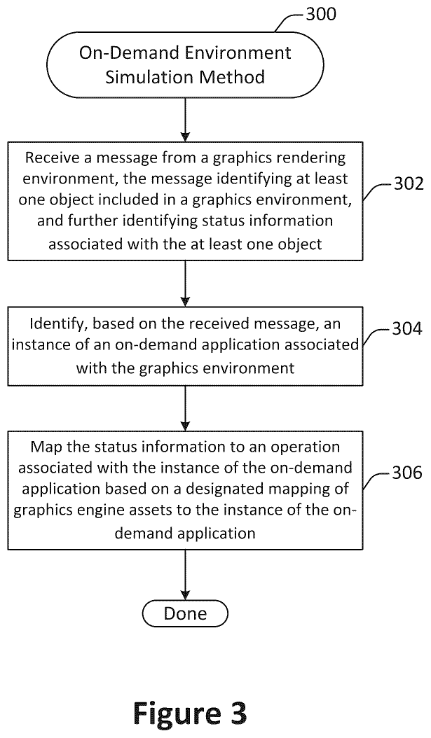

FIG. 3 illustrates an example of a method for on-demand environment simulation, performed in accordance with some embodiments. As similarly discussed above, components of a computing platform may communicate with a graphics rendering environment to simulate and model components of on-demand applications hosted by the computing platform. Accordingly, a method, such as method 300, may be performed to provide communicative coupling between the two environments to facilitate simulation of the on-demand application using the graphics rendering environment.

Method 300 may perform operation 302 during which a message may be received from a graphics rendering environment. In various embodiments, the message may have been generated, at least in part, by a graphics engine, and may identify at least one object included in a graphics rendering environment. The message may also identify status information associated with the at least one object. Accordingly, the graphics rendering environment may include a representation of multiple three-dimensional objects, and the message may identify at least one of the three dimensional objects as well as status information associated with that object. As will be discussed in greater detail below, the status information may identify one or more physical properties of the object as well as a change associated with that property.

Method 300 may perform operation 304 during which an instance of an on-demand application may be identified based on the received message. In some embodiments, a first mapping may be stored and maintained at, for example, the computing platform, and the first mapping may include one or more identifiers configured to identify an instance of a graphics rendering environment and graphics engine, and further identify an instance of an on-demand application. In this way, messages received from the graphics rendering environment may be directed to the appropriate instance of the on-demand application based on the first mapping. In some embodiments, the first mapping may be generated during an instantiation process of the instance of the graphics rendering environment and/or the instance of the on-demand application. In one example, the first mapping may be generated responsive to a user request, and may be generated dynamically in response to that request.

Method 300 may perform operation 306 during which the status information may be mapped to an operation associated with the instance of the on-demand application based on a second mapping that may be a designated mapping of graphics engine assets to the instance of the on-demand application. Accordingly, as will be discussed in greater detail below, the second mapping may be configured to map objects included in the graphics rendering environment to objects included in the on-demand application. The second mapping may also be configured to map actions and changes in status information within the graphics rendering environment to objects and operations included in the on-demand application. In this way, a change or modification to a three-dimensional object within the graphics rendering environment may be mapped to a change in a data structure of the on-demand application, such as a process flow. It will be appreciated that the first mapping and second mapping may be bidirectional and thus be used to map components of the graphics rendering environment to components of the on-demand application, or visa versa.

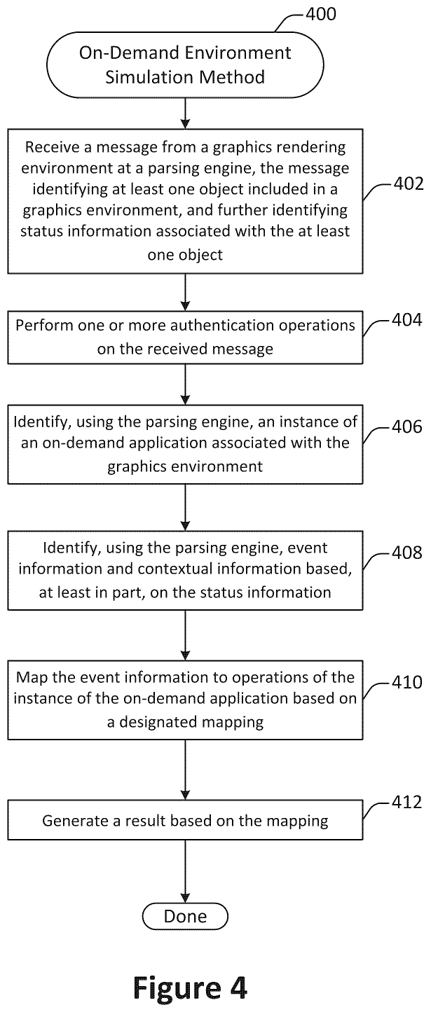

FIG. 4 illustrates another example of a method for on-demand environment simulation, performed in accordance with some embodiments. As similarly discussed above, components of a computing platform may communicate with a graphics rendering environment to simulate and model components of on-demand applications hosted by the computing platform. Accordingly, a method, such as method 400, may be performed to provide communicative coupling between the two environments to facilitate mapping of assets and interpretation of commands and calls between environments.

Method 400 may perform operation 402 during which a message may be received from a graphics rendering environment at a parsing engine. As similarly discussed above, the message may have been generated, at least in part, by a graphics engine, and may identify at least one object included in a graphics rendering environment. The message may also identify status information associated with the at least one object. Accordingly, the message may identify at least one three-dimensional object as well as status information associated with that object.

In various embodiments, the parsing engine may be included in the computing platform. For example, the parsing engine may be included in a service layer of the computing platform that provides an interface between components of the computing platform and external entities, such as the graphics rendering environment that may be implemented on an application server. Accordingly, the parsing engine may be implemented as a service within a service layer, as may be provided by MuleSoft®. As will be discussed in greater detail below, the parsing engine may be configured to extract information included in the message, and generate a data object that is routed to an appropriate instance of an on-demand application based on such extracted information.

Method 400 may perform operation 404 during which one or more authentication operations may be performed. Accordingly, upon receiving the message, authentication operations may be performed to validate contents of the message as well as determine whether or not the message should be provided to any downstream components within the computing platform. Accordingly, the message may include credential information, and such credential information may be verified based on one or more authentication parameters determined by the on-demand application. For example, a security password or other security identifier may have been previously determined by the on-demand application as part of an initial configuration process for both the on-demand application and the graphics rendering environment. It will be appreciated that any suitable authentication and/or verification technique may be used.

Method 400 may perform operation 406 during which an instance of an on-demand application may be identified based on the received message. As similarly discussed above, a first mapping may be stored and maintained at the computing platform, and the first mapping may include one or more identifiers configured to identify an instance of a graphics rendering environment and graphics engine, and further identify an associated instance of an on-demand application. Accordingly, the parsing engine may extract a unique identifier associated with the instance of the graphics rendering environment and/or graphics engine that generated the message, and the parsing engine may map that unique identifier to an instance of an on-demand application based on the first mapping.

Method 400 may perform operation 408 during which event information and contextual information may be identified by the parsing engine. Accordingly, the parsing engine may additionally extract event information that identifies one or more actions and/or events that may have occurred within the graphics rendering environment. For example, such actions and events may include movement of an object, collision or contact between two objects, change of an environmental parameter, or any other change associated with assets within the graphics rendering environment. The contextual information may include additional data and metadata associated with the event, such as dimensions and physical parameters of an object underlying an event as well as dependency information between objects within the graphics rendering environment.

Method 400 may perform operation 410 during which the event information may be mapped to operations of the on-demand application based on a second mapping. As similarly discussed above, the second mapping may be a designated mapping of graphics engine assets to components of the instance of the on-demand application. Accordingly, the second mapping may be configured to map objects included in the graphics rendering environment to objects included in the on-demand application. The second mapping may also be configured to map actions and changes associated with such objects within the graphics rendering environment to objects and operations included in a data structure of the on-demand application, such as a process flow. In this way, a change or modification to a three-dimensional object within the graphics rendering environment may be mapped to a change in a data structure of the on-demand application, such as a process flow. As also similarly discussed above, the first mapping and second mapping may be bidirectional and thus be used to map components of the graphics rendering environment to components of the on-demand application, or visa versa. In various embodiments, implementation of such mapping may be achieved via use of a scripting engine and a parsing engine or other interface component, as discussed above.

Method 400 may perform operation 412 during which a result may be generated based on the mapping. In various embodiments, the result may be a result object that has a format and structure native to the on-demand application. Accordingly, the result may be configured to be ingested by the on-demand application without additional processing or translation. In one example, the result may be ingested by the on-demand application as an event within the context of the on-demand application. For example, the event may be received and processed by the on-demand application as an event within a process flow of the on-demand application.

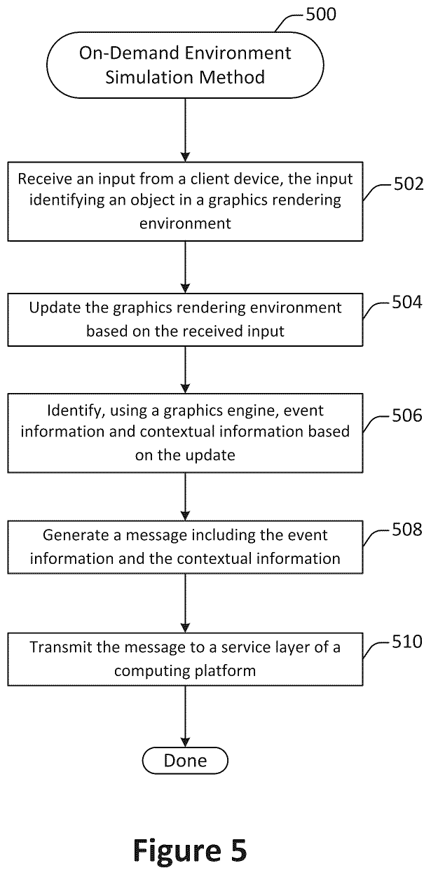

FIG. 5 illustrates an additional example of a method for on-demand environment simulation, performed in accordance with some embodiments. As similarly discussed above, components of a computing platform may communicate with a graphics rendering environment to simulate and model components of on-demand applications hosted by the computing platform. In various embodiments, a method, such as method 500, may be performed to additionally provide communicative coupling between the two environments and a client device to facilitate processing of user inputs to modify the graphics rendering environment and an instance of the on-demand application.

Method 500 may perform operation 502 during which an input may be received from a client device. In various embodiments the client device may be a device operated by an end user, and may be a device such as a personal computer or a smart phone. Such a user may be a user of an on-demand application hosted by a computing platform, and may have a user account within an organization represented within the on-demand application. In some embodiments, an application may be executed on the client device that is configured to provide a web-based interface to the on-demand application, as similarly discussed above with reference to FIG. 1 and in greater detail below in FIG. 9.

In various embodiments, the application executed on the client device may also provide a web-based interface to a graphics rendering environment. For example, the graphics rendering environment may be configured to generate and render a graphical environment using a graphics engine and associated components, and a rendered output of that graphical environment may be provided to the user on a display of the client device. Moreover, the graphical environment may be configured to receive inputs from the user via the client device. For example, the user may provide an input that identifies one or more changes to the graphical environment, such as a creation of a new asset, or a change to an existing asset.

Method 500 may perform operation 504 during which the graphics rendering environment may be updated based on the received input. Accordingly, the graphics rendering environment may receive the input, and may identify one or more changes to be made based on the received input. For example, the input may identify an asset within the graphical environment, and may also identify a change, such as a positional change in which the user has moved a location of the identified asset. Accordingly, during operation 504, the received input may be parsed to identify the identified asset and the identified change. In various embodiments, the graphics engine may also identify additional changes based on one or more dependencies between the identified asset and other assets within the graphical environment based, at least in part, on physics parameters of the graphics engine. For example, the identified movement of the asset may cause a collision with another asset that may move the other asset as well. Such dependencies may be determined based on the previously determined physics parameters of the graphics engine as well as any custom parameters that may have been determined during a configuration of the graphical environment. In various embodiments, the graphical environment may be updated based on the identified changes such that representation of assets within the graphical environment reflects the identified changes. It will be appreciated that the rendered graphical output provided to the client device may also be updated.

Method 500 may perform operation 506 during which event information and contextual information may be identified based on the update. In various embodiments, the event information may identify the changes made to the graphical environment. Accordingly, the event information may identify all changes made during the update to the graphical environment, and may also include identifiers of assets associated with such changes. Accordingly, the event information may include a changelog of assets within the graphical environment. In various embodiments, the changes and assets may also be used to identify contextual information which may include associated data objects and metadata. For example, contextual information for an identified asset may include physical information underlying the asset, such as physical dimensions and physics parameters such as a material, weight, and any other suitable information.

Method 500 may perform operation 508 during which a message may be generated that includes the event information and the contextual information. Accordingly, a message may be generated that packages the event information and the contextual information into a message capable of being received at a computing platform. For example, the event information and the contextual information may be included as a data payload of a message configured to have a format that may be interpreted by a service layer of the computing platform.

Method 500 may perform operation 510 during which the message may be transmitted to a service layer of a computing platform. Accordingly, the message may be transmitted via a network and may be received at the computing platform to be processed, as similarly discussed above. It will be appreciated that in an example where the graphics rendering environment is included in the computing platform, such transmission of the event information and the contextual information may occur internally within the architecture of the computing platform via the service layer.

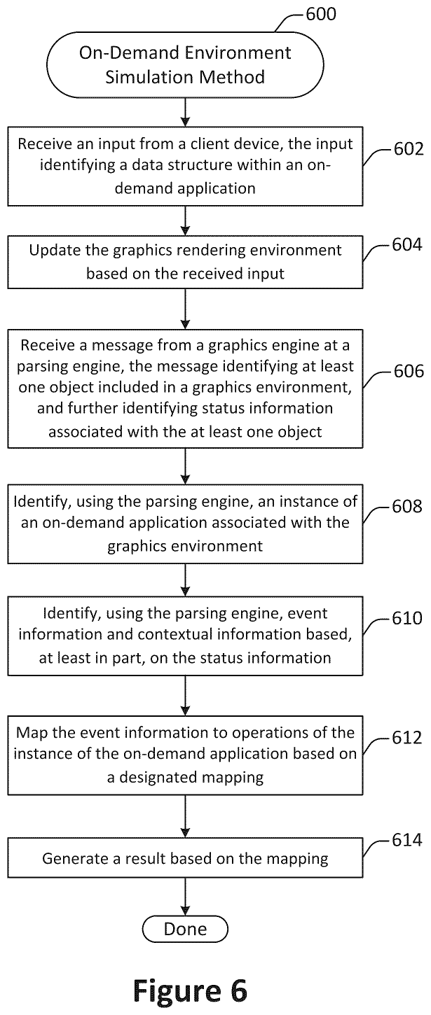

FIG. 6 illustrates another example of a method for on-demand environment simulation, performed in accordance with some embodiments. As similarly discussed above, components of a computing platform may communicate with a graphics rendering environment to simulate and model components of on-demand applications hosted by the computing platform. In various embodiments, a method, such as method 600, may be performed to provide communicative coupling with a client device to facilitate processing of user inputs to modify an instance of the on-demand application and the graphics rendering environment.

Method 600 may perform operation 602 during which an input may be received from a client device, the input identifying a data structure within an on-demand application. Accordingly, an input may be provided by a user to a client device via a web-based interface provided by an application executed on the client device. The input may identify a data structure within the on-demand application. In one example, the user has an account and a role within the on-demand application, and may provide an input to the on-demand application based on a level of access afforded by that role. Moreover, the input may be provided for a particular data structure, such as a process flow.

In one example, the process flow may be a work flow used to model a sequence of operations within the work flow, as similarly discussed above. Accordingly, the on-demand application may be a work flow management application, such as Force.com, and the data structure may define a sequence of operations within the work flow, and dependencies between them. In this way, the data structure may model the work flow and manage a sequence of operations defined by the work flow. In this example, the user input may identify a change of a status association with one of the operations included within the work flow, such as a completion of a task or occurrence of an event.

Method 600 may perform operation 604 during which the graphics rendering environment may be updated based on the received input. Accordingly, the identified data structure and change may be mapped to assets of a graphics rendering environment associated with the on-demand application, and the results of the mapping may be provided to the graphics rendering environment to update a graphical environment within it. Such mapping may be performed by a component of the service layer of the on-demand application based on a reverse mapping, as similarly discussed above.

Method 600 may perform operation 606 during which a message may be received from the graphics engine at a parsing engine of the one-demand application. Accordingly, the graphics rendering environment may perform the update of the graphical environment and generate a message based on the update, as discussed above in FIG. 5. The message may include event information and contextual information that identifies at least one object included in the graphical environment, and further identifies status information associated with the at least one object. The message may be received at the parsing engine that may be included in a service layer of the computing platform.

Method 600 may perform operation 608 during which an instance of the on-demand application associated with the graphics rendering environment may be identified. Accordingly, as similarly discussed above, a parsing engine included in a service layer of the computing platform may be configured to receive and process the received message to extract information and route the extracted information within the architecture of the computing platform. In one example, a first mapping may be stored and maintained at the computing platform, and the first mapping may include one or more identifiers configured to identify an instance of a graphics rendering environment and graphics engine, and further identify an associated instance of an on-demand application. Accordingly, the parsing engine may extract a unique identifier associated with the instance of the graphics rendering environment and/or graphics engine that generated the message, and the parsing engine may map that unique identifier to an instance of an on-demand application based on the first mapping.

Method 600 may perform operation 610 during which event information and contextual information may be identified based, at least in part, on the status information. As similarly discussed above, the parsing engine may additionally extract event information that identifies one or more actions and/or events that may have occurred within the graphics rendering environment. More specifically, the event information may identify actions and events that were included in the update of the graphics rendering environment. Accordingly, such actions and events may be associated with assets identified based on a mapping associated with the received user input as well as one or more dependencies defined within the graphics rendering environment. As also discussed above, the contextual information may include additional data and metadata associated with each event.

Method 600 may perform operation 612 during which the event information may be mapped to operations of the instance of the on-demand application based on a designated mapping. As similarly discussed above, the designated mapping may be a second mapping of graphics engine assets to components of the instance of the on-demand application. Accordingly, the second mapping may be configured to map objects included in the graphics rendering environment to objects included in the on-demand application. The second mapping may also be configured to map actions and changes associated with such objects within the graphics rendering environment to objects and operations included in a data structure of the on-demand application, such as a process flow. In one example, updates to additional assets within the graphical environment may be mapped to additional operations within the data structure of the on-demand application, which may be a work flow data structure. In this way, changes and updates made based on dependencies within the graphical environment may be propagated to changes and updates within the data structure of the on-demand application.

Method 600 may perform operation 614 during which a result may be generated based on the mapping. As similarly discussed above, the result may be a result object that has a format and structure native to the on-demand application. Accordingly, the result may be configured to be ingested by the on-demand application without additional processing or translation. In one example, the result may be ingested by the on-demand application as one or more events and/or operations within the context of a data structure of the on-demand application. For example, one or more events may be received and processed by the on-demand application as events and operations within a process flow of the on-demand application.

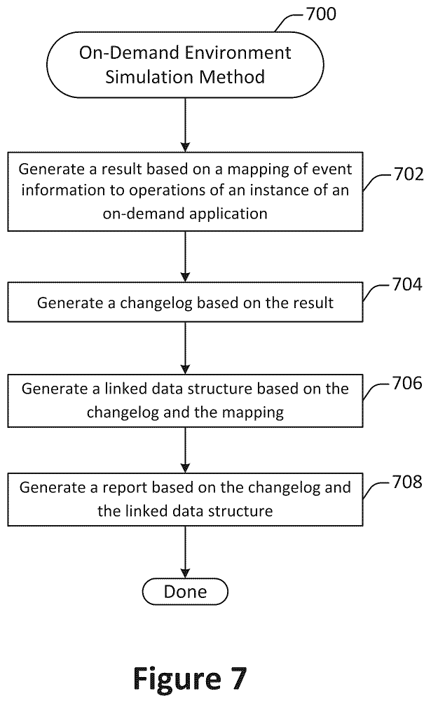

FIG. 7 illustrates an example of a method for on-demand environment simulation, performed in accordance with some embodiments. As will be discussed in greater detail below, a method, such as method 700, may be performed to generate a report that identifies changes and updates that have been made within an instance of an on-demand application, as well as provide custom links between the instance of the on-demand application and an associated graphics rendering environment.

Method 700 may perform operation 702 during which a result may be generated based on a mapping of event information to operations of an instance of an on-demand application. As similarly discussed above, the result may be a result object that has a format and structure native to the on-demand application. In one example, the result may identify one or more events and/or operations within the context of a data structure of the on-demand application that were determined based on events within an associated graphical environment. As discussed above, such events may have been mapped to events and operations within a process flow of the on-demand application.

Method 700 may perform operation 704 during which a changelog may be generated based on the result. In various embodiments, the changelog may identify all changes made to the on-demand application based on the ingestion of the result. For example, the changelog may identify all changes made to operations within a process flow, such as a work flow, of the on-demand application. Such a changelog may include an identifier that identifies the operation within the data structure, as well as one or more identifiers that identify the change that was made, such as change of a status flag or other data field.

Method 700 may perform operation 706 during which a linked data structure may be generated based on the changelog and the mapping. In various embodiments, the linked data structure is configured to identify an associated asset within the graphical environment for each of the changes identified within the changelog. As will be discussed in greater detail below, such a linked data structure may be used to generate interactive links that may issue a function call to the associated graphics rendering environment.

Method 700 may perform operation 708 during which a report may be generated based on the changelog and the linked data structure. Accordingly, the report may be configured to be displayed in a display device of, for example, a client machine, and may be configured to provide a graphical representation of changes made to a data structure of the on-demand application. Accordingly, the report may be configured to display data fields identifying the operations that occurred and/or were changed, as well as display data fields that identify what the changes were for each operation. Such changes may be displayed as a timeline or changelog. Moreover, a link may also be generated for each change that links to the corresponding asset within the graphical environment. In various embodiments, the link is configured to cause invocation of the graphics rendering environment such that when a user interacts with the link by, for example, clicking on it, the user is provided with a user interface to access the graphics rendering environment, as well as the asset that was linked to such that the user may seamlessly access the graphics rendering environment to view the corresponding asset change, and seamlessly toggle between the on-demand application and the graphics rendering environment.

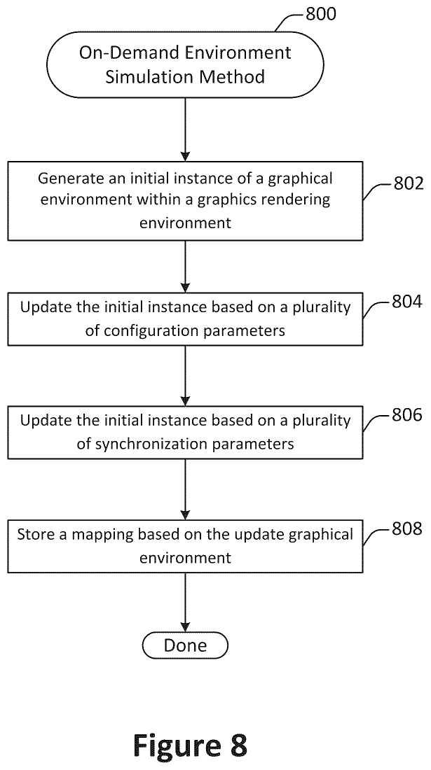

FIG. 8 illustrates an additional example of a method for on-demand environment simulation, performed in accordance with some embodiments. As will be discussed in greater detail below, a method, such as method 800, may be performed to configure an instance of a graphics rendering environment and generate a mapping between the graphics rendering environment and an instance of an on-demand application. In this way, a mapping may be generated that allows a component of a service layer of the on-demand application to facilitate interactivity between the two.

Method 800 may perform operation 802 during which an initial instance of a graphical environment may be generated within a graphics rendering environment. In various embodiments, the initial instance may be generated based on a template or may be generated by a user based on a library of assets and/or one or more custom assets. As discussed above, the graphics rendering environment may be a graphics rendering tool provided by an entity such as Unity® or Unreal®. The initial instance of the graphical environment may be a new file or data record configured to represent a virtual simulation or representation of physical assets within a space defined by initial configuration parameters. In some embodiments, a template may have been previously generated by a user or other entity, such as an administrator, and may include a preconfigured arrangement of assets and associated properties. In another example, a user may build an initial configuration from scratch. In yet another example, a user may perform additional configuration and modification to an existing template to create the initial instance. In some embodiments, the initial instance may be automatically generated based on a designated mapping of on-demand application operations to assets, and an imported data structure file that identifies a structure of operations within an instance of the on-demand application.

Method 800 may perform operation 804 during which the initial instance may be updated based on a plurality of configuration parameters. In various embodiments, the configuration parameters may be provided by a user and may be used to further configure the initial instance of the graphical environment. For example, the user may further configure the initial instance by modifying or deleting assets, or rearranging them. The user may also specify one or more constraints to be applied to the graphical environment, such as one or more failure conditions or other permissible and impermissible changes to assets within the graphical environment.

Method 800 may perform operation 806 during which the initial instance may be updated based on a plurality of synchronization parameters. In various embodiments, synchronization parameters may be retrieved from the on-demand application. The synchronization parameters may identify a most recent configuration of the data structure of the on-demand application, and corresponding assets within the graphical rendering environment may be updated based on the previously discussed mapping. In this way, the initial instance of the graphical environment may be updated to reflect the most recent version of the data structure of the on-demand application.

Method 800 may perform operation 808 during which the mapping may be stored based on the update graphical environment. Accordingly, the updated mapping may be stored as a mapping data structure. In some embodiments, the mapping is stored and maintained by a component of the computing platform, such as a service implemented within a service layer of the computing platform. In various embodiments, the mapping may also be stored within the graphics rendering environment. For example, the mapping may be stored in a storage location accessible by a graphics engine of the graphics rendering environment.

FIG. 9 shows a block diagram of an example of an environment 910 that includes an on-demand database service configured in accordance with some implementations. Environment 910 may include user systems 912, network 914, database system 916, processor system 917, application platform 918, network interface 920, tenant data storage 922, tenant data 923, system data storage 924, system data 925, program code 926, process space 928, User Interface (UI) 930, Application Program Interface (API) 932, PL/SOQL 934, save routines 936, application setup mechanism 938, application servers 950-1 through 950-N, system process space 952, tenant process spaces 954, tenant management process space 960, tenant storage space 962, user storage 964, and application metadata 966. Some of such devices may be implemented using hardware or a combination of hardware and software and may be implemented on the same physical device or on different devices. Thus, terms such as “data processing apparatus,” “machine,” “server” and “device” as used herein are not limited to a single hardware device, but rather include any hardware and software configured to provide the described functionality.

An on-demand database service, implemented using system 916, may be managed by a database service provider. Some services may store information from one or more tenants into tables of a common database image to form a multi-tenant database system (MTS). As used herein, each MTS could include one or more logically and/or physically connected servers distributed locally or across one or more geographic locations. Databases described herein may be implemented as single databases, distributed databases, collections of distributed databases, or any other suitable database system. A database image may include one or more database objects. A relational database management system (RDBMS) or a similar system may execute storage and retrieval of information against these objects.

In some implementations, the application platform 918 may be a framework that allows the creation, management, and execution of applications in system 916. Such applications may be developed by the database service provider or by users or third-party application developers accessing the service. Application platform 918 includes an application setup mechanism 938 that supports application developers' creation and management of applications, which may be saved as metadata into tenant data storage 922 by save routines 936 for execution by subscribers as one or more tenant process spaces 954 managed by tenant management process 960 for example. Invocations to such applications may be coded using PL/SOQL 934 that provides a programming language style interface extension to API 932. A detailed description of some PL/SOQL language implementations is discussed in commonly assigned U.S. Pat. No. 7,730,478, titled METHOD AND SYSTEM FOR ALLOWING ACCESS TO DEVELOPED APPLICATIONS VIA A MULTI-TENANT ON-DEMAND DATABASE SERVICE, by Craig Weissman, issued on Jun. 1, 2010, and hereby incorporated by reference in its entirety and for all purposes. Invocations to applications may be detected by one or more system processes. Such system processes may manage retrieval of application metadata 966 for a subscriber making such an invocation. Such system processes may also manage execution of application metadata 966 as an application in a virtual machine.

In some implementations, each application server 950 may handle requests for any user associated with any organization. A load balancing function (e.g., an F5 Big-IP load balancer) may distribute requests to the application servers 950 based on an algorithm such as least-connections, round robin, observed response time, etc. Each application server 950 may be configured to communicate with tenant data storage 922 and the tenant data 923 therein, and system data storage 924 and the system data 925 therein to serve requests of user systems 912. The tenant data 923 may be divided into individual tenant storage spaces 962, which can be either a physical arrangement and/or a logical arrangement of data. Within each tenant storage space 962, user storage 964 and application metadata 966 may be similarly allocated for each user. For example, a copy of a user's most recently used (MRU) items might be stored to user storage 964. Similarly, a copy of MRU items for an entire tenant organization may be stored to tenant storage space 962. A UI 930 provides a user interface and an API 932 provides an application programming interface to system 916 resident processes to users and/or developers at user systems 912.

System 916 may implement a web-based process flow management system. For example, in some implementations, system 916 may include application servers configured to implement and execute work flow management software applications such as Force.com®. The application servers may be configured to provide related data, code, forms, web pages and other information to and from user systems 912. Additionally, the application servers may be configured to store information to, and retrieve information from a database system. Such information may include related data, objects, and/or Webpage content. With a multi-tenant system, data for multiple tenants may be stored in the same physical database object in tenant data storage 922, however, tenant data may be arranged in the storage medium(s) of tenant data storage 922 so that data of one tenant is kept logically separate from that of other tenants. In such a scheme, one tenant may not access another tenant's data, unless such data is expressly shared.

Several elements in the system shown in FIG. 9 include conventional, well-known elements that are explained only briefly here. For example, user system 912 may include processor system 912A, memory system 912B, input system 912C, and output system 912D. A user system 912 may be implemented as any computing device(s) or other data processing apparatus such as a mobile phone, laptop computer, tablet, desktop computer, or network of computing devices. User system 12 may run an internet browser allowing a user (e.g., a subscriber of an MTS) of user system 912 to access, process and view information, pages and applications available from system 916 over network 914. Network 914 may be any network or combination of networks of devices that communicate with one another, such as any one or any combination of a LAN (local area network), WAN (wide area network), wireless network, or other appropriate configuration.

The users of user systems 912 may differ in their respective capacities, and the capacity of a particular user system 912 to access information may be determined at least in part by “permissions” of the particular user system 912. As discussed herein, permissions generally govern access to computing resources such as data objects, components, and other entities of a computing system, such as a work flow management system, a graphics rendering system, a social networking system, and/or a CRM database system. “Permission sets” generally refer to groups of permissions that may be assigned to users of such a computing environment. For instance, the assignments of users and permission sets may be stored in one or more databases of System 916. Thus, users may receive permission to access certain resources. A permission server in an on-demand database service environment can store criteria data regarding the types of users and permission sets to assign to each other. For example, a computing device can provide to the server data indicating an attribute of a user (e.g., geographic location, industry, role, level of experience, etc.) and particular permissions to be assigned to the users fitting the attributes. Permission sets meeting the criteria may be selected and assigned to the users. Moreover, permissions may appear in multiple permission sets. In this way, the users can gain access to the components of a system.

In some an on-demand database service environments, an Application Programming Interface (API) may be configured to expose a collection of permissions and their assignments to users through appropriate network-based services and architectures, for instance, using Simple Object Access Protocol (SOAP) Web Service and Representational State Transfer (REST) APIs.

In some implementations, a permission set may be presented to an administrator as a container of permissions. However, each permission in such a permission set may reside in a separate API object exposed in a shared API that has a child-parent relationship with the same permission set object. This allows a given permission set to scale to millions of permissions for a user while allowing a developer to take advantage of joins across the API objects to query, insert, update, and delete any permission across the millions of possible choices. This makes the API highly scalable, reliable, and efficient for developers to use.

In some implementations, a permission set API constructed using the techniques disclosed herein can provide scalable, reliable, and efficient mechanisms for a developer to create tools that manage a user's permissions across various sets of access controls and across types of users. Administrators who use this tooling can effectively reduce their time managing a user's rights, integrate with external systems, and report on rights for auditing and troubleshooting purposes. By way of example, different users may have different capabilities with regard to accessing and modifying application and database information, depending on a user's security or permission level, also called authorization. In systems with a hierarchical role model, users at one permission level may have access to applications, data, and database information accessible by a lower permission level user, but may not have access to certain applications, database information, and data accessible by a user at a higher permission level.

As discussed above, system 916 may provide on-demand database service to user systems 912 using an MTS arrangement. By way of example, one tenant organization may be a company that employs a sales force where each salesperson uses system 916 to manage their sales process. Thus, a user in such an organization may maintain contact data, leads data, customer follow-up data, performance data, goals and progress data, etc., all applicable to that user's personal sales process (e.g., in tenant data storage 922). In this arrangement, a user may manage his or her sales efforts and cycles from a variety of devices, since relevant data and applications to interact with (e.g., access, view, modify, report, transmit, calculate, etc.) such data may be maintained and accessed by any user system 912 having network access.

When implemented in an MTS arrangement, system 916 may separate and share data between users and at the organization-level in a variety of manners. For example, for certain types of data each user's data might be separate from other users' data regardless of the organization employing such users. Other data may be organization-wide data, which is shared or accessible by several users or potentially all users form a given tenant organization. Thus, some data structures managed by system 916 may be allocated at the tenant level while other data structures might be managed at the user level. Because an MTS might support multiple tenants including possible competitors, the MTS may have security protocols that keep data, applications, and application use separate. In addition to user-specific data and tenant-specific data, system 916 may also maintain system-level data usable by multiple tenants or other data. Such system-level data may include industry reports, news, postings, and the like that are sharable between tenant organizations.

In some implementations, user systems 912 may be client systems communicating with application servers 950 to request and update system-level and tenant-level data from system 916. By way of example, user systems 912 may send one or more queries requesting data of a database maintained in tenant data storage 922 and/or system data storage 924. An application server 950 of system 916 may automatically generate one or more SQL statements (e.g., one or more SQL queries) that are designed to access the requested data. System data storage 924 may generate query plans to access the requested data from the database.

The database systems described herein may be used for a variety of database applications. By way of example, each database can generally be viewed as a collection of objects, such as a set of logical tables, containing data fitted into predefined categories. A “table” is one representation of a data object, and may be used herein to simplify the conceptual description of objects and custom objects according to some implementations. It should be understood that “table” and “object” may be used interchangeably herein. Each table generally contains one or more data categories logically arranged as columns or fields in a viewable schema. Each row or record of a table contains an instance of data for each category defined by the fields. For example, a CRM database may include a table that describes a customer with fields for basic contact information such as name, address, phone number, fax number, etc. Another table might describe a purchase order, including fields for information such as customer, product, sale price, date, etc. In some multi-tenant database systems, standard entity tables might be provided for use by all tenants. For CRM database applications, such standard entities might include tables for case, account, contact, lead, and opportunity data objects, each containing pre-defined fields. It should be understood that the word “entity” may also be used interchangeably herein with “object” and “table”.

In some implementations, tenants may be allowed to create and store custom objects, or they may be allowed to customize standard entities or objects, for example by creating custom fields for standard objects, including custom index fields. Commonly assigned U.S. Pat. No. 7,779,039, titled CUSTOM ENTITIES AND FIELDS IN A MULTI-TENANT DATABASE SYSTEM, by Weissman et al., issued on Aug. 17, 2010, and hereby incorporated by reference in its entirety and for all purposes, teaches systems and methods for creating custom objects as well as customizing standard objects in an MTS. In certain implementations, for example, all custom entity data rows may be stored in a single multi-tenant physical table, which may contain multiple logical tables per organization. It may be transparent to customers that their multiple “tables” are in fact stored in one large table or that their data may be stored in the same table as the data of other customers.

FIG. 10A shows a system diagram of an example of architectural components of an on-demand database service environment 1000, configured in accordance with some implementations. A client machine located in the cloud 1004 may communicate with the on-demand database service environment via one or more edge routers 1008 and 1012. A client machine may include any of the examples of user systems ?12 described above. The edge routers 1008 and 1012 may communicate with one or more core switches 1020 and 1024 via firewall 1016. The core switches may communicate with a load balancer 1028, which may distribute server load over different pods, such as the pods 1040 and 1044 by communication via pod switches 1032 and 1036. The pods 1040 and 1044, which may each include one or more servers and/or other computing resources, may perform data processing and other operations used to provide on-demand services. Components of the environment may communicate with a database storage 1056 via a database firewall 1048 and a database switch 1052.

Accessing an on-demand database service environment may involve communications transmitted among a variety of different components. The environment 1000 is a simplified representation of an actual on-demand database service environment. For example, some implementations of an on-demand database service environment may include anywhere from one to many devices of each type. Additionally, an on-demand database service environment need not include each device shown, or may include additional devices not shown, in FIGS. 10A and 10B.

The cloud 1004 refers to any suitable data network or combination of data networks, which may include the Internet. Client machines located in the cloud 1004 may communicate with the on-demand database service environment 1000 to access services provided by the on-demand database service environment 1000. By way of example, client machines may access the on-demand database service environment 1000 to retrieve, store, edit, and/or process work flow information.

In some implementations, the edge routers 1008 and 1012 route packets between the cloud 1004 and other components of the on-demand database service environment 1000. The edge routers 1008 and 1012 may employ the Border Gateway Protocol (BGP). The edge routers 1008 and 1012 may maintain a table of IP networks or ‘prefixes’, which designate network reachability among autonomous systems on the internet.

In one or more implementations, the firewall 1016 may protect the inner components of the environment 1000 from internet traffic. The firewall 1016 may block, permit, or deny access to the inner components of the on-demand database service environment 1000 based upon a set of rules and/or other criteria. The firewall 1016 may act as one or more of a packet filter, an application gateway, a stateful filter, a proxy server, or any other type of firewall.

In some implementations, the core switches 1020 and 1024 may be high-capacity switches that transfer packets within the environment 1000. The core switches 1020 and 1024 may be configured as network bridges that quickly route data between different components within the on-demand database service environment. The use of two or more core switches 1020 and 1024 may provide redundancy and/or reduced latency.

In some implementations, communication between the pods 1040 and 1044 may be conducted via the pod switches 1032 and 1036. The pod switches 1032 and 1036 may facilitate communication between the pods 1040 and 1044 and client machines, for example via core switches 1020 and 1024. Also or alternatively, the pod switches 1032 and 1036 may facilitate communication between the pods 1040 and 1044 and the database storage 1056. The load balancer 1028 may distribute workload between the pods, which may assist in improving the use of resources, increasing throughput, reducing response times, and/or reducing overhead. The load balancer 1028 may include multilayer switches to analyze and forward traffic.

In some implementations, access to the database storage 1056 may be guarded by a database firewall 1048, which may act as a computer application firewall operating at the database application layer of a protocol stack. The database firewall 1048 may protect the database storage 1056 from application attacks such as structure query language (SQL) injection, database rootkits, and unauthorized information disclosure. The database firewall 1048 may include a host using one or more forms of reverse proxy services to proxy traffic before passing it to a gateway router and/or may inspect the contents of database traffic and block certain content or database requests. The database firewall 1048 may work on the SQL application level atop the TCP/IP stack, managing applications' connection to the database or SQL management interfaces as well as intercepting and enforcing packets traveling to or from a database network or application interface.

In some implementations, the database storage 1056 may be an on-demand database system shared by many different organizations. The on-demand database service may employ a single-tenant approach, a multi-tenant approach, a virtualized approach, or any other type of database approach. Communication with the database storage 1056 may be conducted via the database switch 1052. The database storage 1056 may include various software components for handling database queries. Accordingly, the database switch 1052 may direct database queries transmitted by other components of the environment (e.g., the pods 1040 and 1044) to the correct components within the database storage 1056.

FIG. 10B shows a system diagram further illustrating an example of architectural components of an on-demand database service environment, in accordance with some implementations. The pod 1044 may be used to render services to user(s) of the on-demand database service environment 1000. The pod 1044 may include one or more content batch servers 1064, content search servers 1068, query servers 1082, file servers 1086, access control system (ACS) servers 1080, batch servers 1084, and app servers 1088. Also, the pod 1044 may include database instances 1090, quick file systems (QFS) 1092, and indexers 1094. Some or all communication between the servers in the pod 1044 may be transmitted via the switch 1036.

In some implementations, the app servers 1088 may include a framework dedicated to the execution of procedures (e.g., programs, routines, scripts) for supporting the construction of applications provided by the on-demand database service environment 1000 via the pod 1044. One or more instances of the app server 1088 may be configured to execute all or a portion of the operations of the services described herein.

In some implementations, as discussed above, the pod 1044 may include one or more database instances 1090. A database instance 1090 may be configured as an MTS in which different organizations share access to the same database, using the techniques described above. Database information may be transmitted to the indexer 1094, which may provide an index of information available in the database 1090 to file servers 1086. The QFS 1092 or other suitable filesystem may serve as a rapid-access file system for storing and accessing information available within the pod 1044. The QFS 1092 may support volume management capabilities, allowing many disks to be grouped together into a file system. The QFS 1092 may communicate with the database instances 1090, content search servers 1068 and/or indexers 1094 to identify, retrieve, move, and/or update data stored in the network file systems (NFS) 1096 and/or other storage systems.

In some implementations, one or more query servers 1082 may communicate with the NFS 1096 to retrieve and/or update information stored outside of the pod 1044. The NFS 1096 may allow servers located in the pod 1044 to access information over a network in a manner similar to how local storage is accessed. Queries from the query servers 1022 may be transmitted to the NFS 1096 via the load balancer 1028, which may distribute resource requests over various resources available in the on-demand database service environment 1000. The NFS 1096 may also communicate with the QFS 1092 to update the information stored on the NFS 1096 and/or to provide information to the QFS 1092 for use by servers located within the pod 1044.

In some implementations, the content batch servers 1064 may handle requests internal to the pod 1044. These requests may be long-running and/or not tied to a particular customer, such as requests related to log mining, cleanup work, and maintenance tasks. The content search servers 1068 may provide query and indexer functions such as functions allowing users to search through content stored in the on-demand database service environment 1000. The file servers 1086 may manage requests for information stored in the file storage 1098, which may store information such as documents, images, basic large objects (BLOBs), etc. The query servers 1082 may be used to retrieve information from one or more file systems. For example, the query system 1082 may receive requests for information from the app servers 1088 and then transmit information queries to the NFS 1096 located outside the pod 1044. The ACS servers 1080 may control access to data, hardware resources, or software resources called upon to render services provided by the pod 1044. The batch servers 1084 may process batch jobs, which are used to run tasks at specified times. Thus, the batch servers 1084 may transmit instructions to other servers, such as the app servers 1088, to trigger the batch jobs.

While some of the disclosed implementations may be described with reference to a system having an application server providing a front end for an on-demand database service capable of supporting multiple tenants, the disclosed implementations are not limited to multi-tenant databases nor deployment on application servers. Some implementations may be practiced using various database architectures such as ORACLE®, DB2® by IBM and the like without departing from the scope of present disclosure.

FIG. 11 illustrates one example of a computing device. According to various embodiments, a system 1100 suitable for implementing embodiments described herein includes a processor 1101, a memory module 1103, a storage device 1105, an interface 1111, and a bus 1115 (e.g., a PCI bus or other interconnection fabric.) System 1100 may operate as variety of devices such as an application server, a database server, or any other device or service described herein. Although a particular configuration is described, a variety of alternative configurations are possible. The processor 1101 may perform operations such as those described herein. Instructions for performing such operations may be embodied in the memory 1103, on one or more non-transitory computer readable media, or on some other storage device. Various specially configured devices can also be used in place of or in addition to the processor 1101. The interface 1111 may be configured to send and receive data packets over a network. Examples of supported interfaces include, but are not limited to: Ethernet, fast Ethernet, Gigabit Ethernet, frame relay, cable, digital subscriber line (DSL), token ring, Asynchronous Transfer Mode (ATM), High-Speed Serial Interface (HSSI), and Fiber Distributed Data Interface (FDDI). These interfaces may include ports appropriate for communication with the appropriate media. They may also include an independent processor and/or volatile RAM. A computer system or computing device may include or communicate with a monitor, printer, or other suitable display for providing any of the results mentioned herein to a user.

Any of the disclosed implementations may be embodied in various types of hardware, software, firmware, computer readable media, and combinations thereof. For example, some techniques disclosed herein may be implemented, at least in part, by computer-readable media that include program instructions, state information, etc., for configuring a computing system to perform various services and operations described herein. Examples of program instructions include both machine code, such as produced by a compiler, and higher-level code that may be executed via an interpreter. Instructions may be embodied in any suitable language such as, for example, Apex, Java, Python, C++, C, HTML, any other markup language, JavaScript, ActiveX, VBScript, or Perl. Examples of computer-readable media include, but are not limited to: magnetic media such as hard disks and magnetic tape; optical media such as flash memory, compact disk (CD) or digital versatile disk (DVD); magneto-optical media; and other hardware devices such as read-only memory (“ROM”) devices and random-access memory (“RAM”) devices. A computer-readable medium may be any combination of such storage devices.

In the foregoing specification, various techniques and mechanisms may have been described in singular form for clarity. However, it should be noted that some embodiments include multiple iterations of a technique or multiple instantiations of a mechanism unless otherwise noted. For example, a system uses a processor in a variety of contexts but can use multiple processors while remaining within the scope of the present disclosure unless otherwise noted. Similarly, various techniques and mechanisms may have been described as including a connection between two entities. However, a connection does not necessarily mean a direct, unimpeded connection, as a variety of other entities (e.g., bridges, controllers, gateways, etc.) may reside between the two entities.

In the foregoing specification, reference was made in detail to specific embodiments including one or more of the best modes contemplated by the inventors. While various implementations have been described herein, it should be understood that they have been presented by way of example only, and not limitation. For example, some techniques and mechanisms are described herein in the context of process flow management. However, the techniques disclosed herein apply to a wide variety of computing environments. Particular embodiments may be implemented without some or all of the specific details described herein. In other instances, well known process operations have not been described in detail in order to avoid unnecessarily obscuring the disclosed techniques. Accordingly, the breadth and scope of the present application should not be limited by any of the implementations described herein, but should be defined only in accordance with the claims and their equivalents.

1. A computing platform implemented using a server system, the computing platform being configurable to cause:
receiving a message from a graphics engine, the message identifying at least one object included in a graphics rendering environment, and further identifying status information associated with the at least one object;
identifying, based on the received message, an instance of an on-demand application associated with the graphics rendering environment; and
mapping the status information to an operation associated with the instance of the on-demand application based on a designated mapping of graphics engine assets to the instance of the on-demand application.

2. The system recited in claim 1, wherein the instance of the on-demand application comprises a process flow data structure.

3. The system recited in claim 2, wherein the process flow data structure comprises:
a first plurality of data objects representing process operations; and
a second plurality if data objects identifying dependencies between at least some of the first plurality of data objects.

4. The system recited in claim 3, wherein the designated mapping is configured to map graphics engine assets to the first plurality of data objects.

5. The system recited in claim 1, wherein the mapping is performed by a service layer of the computing platform.

6. The system recited in claim 5, wherein the designated mapping is stored in the service layer.

7. The system recited in claim 5, wherein the identifying is performed by a parsing engine included in the service layer.

8. The system recited in claim 1, wherein the computing platform being configurable to cause:
generating a result based on the mapping, the result comprising a report.

9. The system recited in claim 8, wherein the report comprises:
a list of changes made in the graphics rendering environment; and
a list of operations performed by the on-demand application.

10. The system recited in claim 9, wherein the report is configured to be displayed as a user interface in a display device.

11. The system recited in claim 9, wherein the report comprises links to the graphics engine assets and the operation.

12. A method comprising:
receiving a message from a graphics engine, the message identifying at least one object included in a graphics rendering environment, and further identifying status information associated with the at least one object;
identifying, based on the received message, an instance of an on-demand application associated with the graphics rendering environment; and
mapping the status information to an operation associated with the instance of the on-demand application based on a designated mapping of graphics engine assets to the instance of the on-demand application.

13. The method recited in claim 12, wherein the instance of the on-demand application comprises a process flow data structure.

14. The method recited in claim 13, wherein the process flow data structure comprises:
a first plurality of data objects representing process operations; and
a second plurality if data objects identifying dependencies between at least some of the first plurality of data objects.

15. The method recited in claim 14, wherein the designated mapping is configured to map graphics engine assets to the first plurality of data objects.

16. The method recited in claim 12, wherein the mapping is performed by a service layer of a computing platform, and wherein the designated mapping is stored in the service layer.

17. The method recited in claim 12, wherein the method further comprises:
generating a result based on the mapping, the result comprising a report, wherein the report comprises:
a list of changes made in the graphics rendering environment; and
a list of operations performed by the on-demand application.

18. One or more non-transitory computer readable media having instructions stored thereon for performing a method, the method comprising:
receiving a message from a graphics engine, the message identifying at least one object included in a graphics rendering environment, and further identifying status information associated with the at least one object;
identifying, based on the received message, an instance of an on-demand application associated with the graphics rendering environment; and
mapping the status information to an operation associated with the instance of the on-demand application based on a designated mapping of graphics engine assets to the instance of the on-demand application.

19. The one or more non-transitory computer readable media of claim 18, wherein the instance of the on-demand application comprises a process flow data structure, and wherein the process flow data structure comprises:
a first plurality of data objects representing process operations; and
a second plurality if data objects identifying dependencies between at least some of the first plurality of data objects.

20. The one or more non-transitory computer readable media of claim 19, wherein the designated mapping is configured to map graphics engine assets to the first plurality of data objects.
